(19) United States
(12) Patent Application Publication
(10) Pub. No.: US 2003/0098474 A1
(43) Pub. Date: May 29, 2003

(54) Program-Controlled unit

(76) Inventors: Herbert Rodig, Neutraubling (DE); Klaus Bendel, Stampe (DE); Boris Vittorelli, Haimhausen (DE)

Correspondence Address: LERNER AND GREENBERG P.A., Post Office Box 2480, Hollywood, FL, 33022-2480, US

(21) Appl. No.: 10/206,304

(22) Filed: Jul. 26, 2002

(30) Foreign Application Priority Data
Jul. 26, 2001 (DE) 101 36 395.8

(51) Int. Cl. H01L 27/10; H01L 23/02; H01L 23/52; H01L 23/34; H01L 23/48; H01L 29/40

(52) U.S. Cl. 257/207; 257/691; 257/208; 257/211; 257/686; 257/723; 257/777

(57) ABSTRACT

A program-controlled unit includes a plurality of semiconductor chips distributed between a plurality of chip carriers that are disposed one above the other and are connected to one another through a bus. Such program-controlled units can be developed, produced, and tested simply, rapidly, and cost-effectively even when they have to be adapted to special requirements.

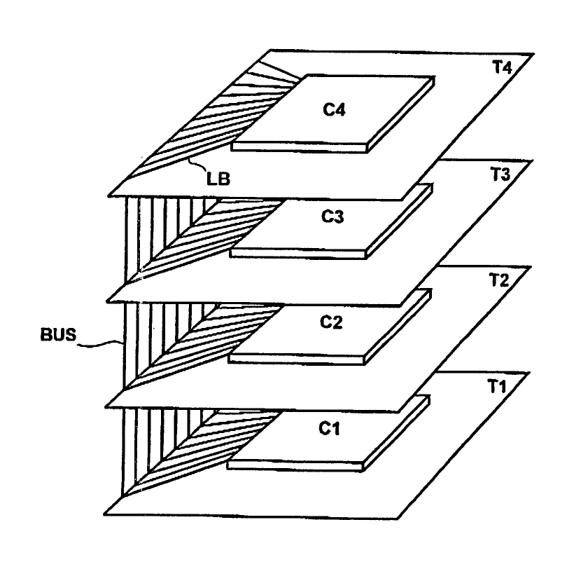

### BACKGROUND OF THE INVENTION

Field of the Invention

The present invention relates to a program-controlled unit.

Program-controlled units such as, for example, microprocessors, microcontrollers, and signal processors have been in the prior art for many years in innumerable embodiments and need no further explanation.

Program-controlled units are generally distinguished by the fact that they can be used extremely diversely. This has the positive effect that they can be produced and sold in very large numbers, as a result of which, their price—measured by the required development and production outlay and the performance—is relatively low.

However, the available program-controlled units are not suitable or are only suitable to a limited extent for specific applications. In such cases, it is not possible to avoid developing and producing program-controlled units tailored specifically to the respective requirements.

However, the development, production, and testing of such program-controlled units are disproportionately complicated and expensive, inter alia, due to the relatively small numbers in which they are required.

### SUMMARY OF THE INVENTION

It is accordingly an object of the invention to provide a program-controlled unit that overcomes the hereinafore-mentioned disadvantages of the heretofore known devices of this general type and that can be developed, produced and tested simply, rapidly and cost-effectively even when it has to be adapted to special requirements.

With the foregoing and other objects in view, there is provided, in accordance with the invention, a program-controlled unit, including a bus, chip carriers disposed one above another and connected to one another through the bus, and semiconductor chips distributed among the chip carriers.

The program-controlled unit according to the invention is distinguished by the fact that it includes a plurality of semiconductor chips, and that the plurality of semiconductor chips are distributed between a plurality of chip carriers that are disposed one above the other and are connected to one another through a bus.

In accordance with another feature of the invention, each of the semiconductor chips have terminals including at least one of input terminals and output terminals, and each of the chip carriers have a lateral edge, electrically conductive structures, the structures having contact points for connection to the terminals of respective ones of the semiconductor chips mounted thereon, and conductor tracks running from the contact points to the lateral edge.

In accordance with a further feature of the invention, the conductor tracks on different ones of the chip carriers are connected to one another at least partly through the bus.

In accordance with an added feature of the invention, the chip carriers are disposed one above another in a chip carrier stack and the bus is formed by a multiplicity of bus lines running laterally at the chip carrier stack.

In accordance with an additional feature of the invention, the bus lines run vertically.

In accordance with yet another feature of the invention, the chip carriers are disposed one above another in a chip carrier stack along a stack direction and the bus lines run along the stack direction.

In accordance with yet a further feature of the invention, the bus lines run parallel to one another.

In accordance with yet an added feature of the invention, the chip carriers disposed one above another define interspaces therebetween and the interspaces between the chip carriers are filled with a filling compound.

In accordance with yet an additional feature of the invention, the conductor tracks and the bus lines are disposed to automatically come into contact with one another during production of the bus lines, and without an additional connection.

In accordance with again another feature of the invention, the conductor tracks to be connected to one another through the bus traverse a course on a respective one of the chip carriers to reach the lateral edge of the respective chip carrier at locations lying directly one above another.

In accordance with again a further feature of the invention, a first given subset of the conductor tracks of one chip carrier is to be connected to a given second subset of the conductor tracks of another chip carrier through a given bus line, and the first given subset and the second given subset of the conductor tracks have courses reaching the lateral edge of a respective one of the chip carriers at a location lying directly one above another, preferably, precisely one above another.

In accordance with a concomitant feature of the invention, the terminals do not include either input terminals or output terminals to be connected to an external memory.

Distributing the program-controlled unit between a plurality of semiconductor chips makes it possible:

for the individual components of the program-controlled unit to be able to be developed, produced and tested individually and independently of one another and consequently comparatively rapidly and simply;

for less consideration to have to be given to interactions between the individual components of the program-controlled unit during the development and during testing;

for there to be no need to accommodate on the same semiconductor chip components that have to be produced according to different methods or are preferably produced according to different methods;

for the individual components of the program-controlled unit to be able to be produced independently of one another using the optimum production method in each case;

for the program-controlled unit to be able to be adapted to the individual requirements solely through a corresponding selection of the semiconductor chip forming it; and

when a semiconductor chip required for such a purpose is not present, only this one semiconductor chip has to be newly developed (the remaining semiconductor chips of the program-controlled unit can continue to be used unchanged).

Configuring the semiconductor chips on chip carriers that are disposed one above the other and are connected to one another through a bus makes it possible:

for the basic construction of the program-controlled unit always to be the same independently of the number, the functions and the properties of the semiconductor chips;

for the replacement of one semiconductor chip by another semiconductor chip and/or the increasing or the reduction of the number of semiconductor chips to be possible at any time without difficulty (without significant changes); and

for it to be possible without difficulty to maintain unchanged the number and the position of the input and/or output terminals of the program-controlled unit independently of the number and the type of semiconductor chips.

The particular construction of the program-controlled unit according to the invention:

enables the unit to be developed, produced, and tested more simply, more rapidly, and more cost-effectively than is the case with a program-controlled unit accommodated on a single semiconductor chip; and

makes it possible to use a program-controlled unit that is modified or improved, for example, by the use of additional or other semiconductor chips, without altering the system, in particular, without altering the layout of the system in which it is used.

Other features that are considered as characteristic for the invention are set forth in the appended claims.

Although the invention is illustrated and described herein as embodied in a program-controlled unit, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

The FIGURE is a diagrammatic illustration of the program-controlled unit according to the invention.

### DESCRIPTION OF THE PREFERRED EMBODIMENTS

Referring now to the single FIGURE of the drawing, it is seen that a program-controlled unit includes a plurality of semiconductor chips and that the plurality of semiconductor chips are distributed between a plurality of chip carriers that are disposed one above the other and are connected to one another through a bus.

In the example considered, the program-controlled unit includes four semiconductor chips each disposed on a dedicated chip carrier. However, at such an early juncture, it shall already be pointed out that the program-controlled unit can contain, in principle, as many semiconductor chips as are desired that can be distributed between as many chip carriers as desired. In such a case, it is also possible for a plurality of semiconductor chips to be disposed on one chip carrier. In addition to the semiconductor chips, other electrical, electronic, electromechanical components, for example, resistors, capacitors, coils, sensors, indicating devices, possibly even loudspeakers and the like, fans, etc., may be provided on the chip carriers. The program-controlled unit may also include carrier elements that do not contain a semiconductor chip but, rather, only components of the type just mentioned, and/or particular wirings, and/or shielding devices (for shielding electromagnetic fields), and/or insulation devices (for protection against excessively high temperatures), etc.

In the FIGURE, the semiconductor chips are designated by the reference symbols C1 to C4, the chip carriers carrying the semiconductor chips are designated by the reference symbols T1 to T4, and the bus that electrically connects the chip carriers T1 to T4 to one another is designated by the reference symbol BUS.

In the example considered, the semiconductor chip C1 is a flash memory used as a program memory, the semiconductor chip C2 is the core of the program-controlled unit, which core executes the instructions to be executed, the semiconductor chip C3 is a DRAM memory used as a data memory, and the semiconductor chip C4 is a semiconductor chip containing a comparison device.

As will be understood even better later, the order in which the semiconductor chips (the chip carriers carrying the semiconductor chips) are disposed one above the other can also be configured differently as desired. Specific circumstances may necessitate a very specific order, however. By way of example, it may be necessary for specific semiconductor chips to be disposed directly one above the other or, in any event, not too far away from one another, and/or for specific semiconductor chips to be disposed at the very top or at the very bottom at the stack, in which case the former may be necessary, for example, if short maximum signal propagation times must not be exceeded, and in which case the latter may be necessary, for example, because the semiconductor chip to be disposed at the top or bottom becomes particularly hot.

The semiconductor chips C1 to C4 are electrically and mechanically connected to the respective chip carriers T1 to T4. By way of example, they are adhesively bonded onto the chip carriers T1 to T4 and are electrically connected to the chip carriers by bonding, or mounted on the chip carriers using the flip-chip technique.

The chip carriers T1 to T4 are, for example, laminar structures composed of ceramic or glass and have electrically conductive structures on their surface carrying the semiconductor chips. These electrically conductive structures include non-illustrated contact points for electrical connection to the input/output terminals (formed by pads, balls, etc.) of the semiconductor chips, and conductor tracks LB running from the contact points to the lateral edge of the chip carriers; the conductor tracks LB extend right up to the edge of the chip carriers T1 to T4 so that, during the production of the lines (running laterally at the chip carrier stack) of the bus, they come into contact with the lines automatically, i.e., without a special connection.

The conductor tracks LB preferably have a course such that those conductor tracks that are to be connected to the same bus line reach the edge of the chip carriers at locations of the chip carriers that lie exactly one above the other; what can thereby be achieved is that the bus BUS can always have the same construction and the same course independently of the type and the number of semiconductor chips and independently of the configuration of the semiconductor chips within the chip carrier stack.

In the example considered, the semiconductor chips are constructed and mounted onto the chip carriers such that the conductor tracks LB can be routed to not cross one another. As a result, the electrically conductive structure provided on the chip carrier can be formed in one layer, that is to say, very simply. In principle, however, the electrically conductive structure provided on the chip carrier could also be formed in a multilayer manner; in the latter case, the chip carriers are preferably chip carriers that contain a plurality of conductor track planes and are constructed in a multilayer manner. When required, the semiconductor chips can also be configured such that the length of specific or all conductor tracks LB is minimal and/or as few interactions as possible result between the conductor tracks.

The interspaces between the chip carriers T1 to T4 carrying the semiconductor chips C1 to C4 are filled with a non-illustrated filling compound. As a result, the configuration becomes an approximately parallelepipedal structure. The side areas of the chip carriers, but at least those regions of the side areas at which the conductor tracks LB reach the latter, remain uncovered. This, and the fact that the configuration has precisely the desired form, is achieved most simply by cutting it from a larger configuration containing preferably a plurality of program-controlled units of the type described. However, it is also possible for the side areas to be uncovered subsequently.

(Bus) lines forming the bus BUS already mentioned are applied on one, a plurality, or all of the vertical side areas of the parallelepiped. In the example considered, these bus lines are produced by applying a metal layer to the areas provided with the bus lines (for example, by spluttering and subsequent electrodeposition), and by removing the non-required parts of the metal layer (for example, by using a laser or by selective etching away). In the example considered, the remaining bus lines run parallel to one another vertically from top to bottom. In such a case, they come into contact with the conductor tracks LB joining the side areas of the chip carriers and, thereby, connect together the mutually associated conductor tracks of the different chip carriers.

The program-controlled unit or “only” the bus BUS can (but need not) be encapsulated by casting or injection-molding with a protective material, for example, a so-called molding compound.

The input and/or output terminals of the program-controlled unit for connecting the program-controlled unit to other components of a system containing these are situated on the underside of the bottommost chip carrier T1 or on a separate carrier element that is preferably the size of a chip carrier and is disposed below the bottommost chip carrier T1 or above the topmost chip carrier T4 and is connected to the chip carriers T1 to T4 (the semiconductor chips C1 to C4 provided thereon) through the bus BUS.

In the example considered, the input and/or output terminals contain no terminals for connection to an external memory. The terminals are not necessary because the required memory can be integrated into the program-controlled unit without difficulty independently of the type of memory required and independently of the storage capacity required.

Such a configuration reduces the number of input and/or output terminals of the program-controlled unit and eliminates the problems that can arise from a possibly required adaptation of the program-controlled unit to an external memory.

It goes without saying that, when required, it is also possible to equip the program-controlled unit with input and/or output terminals for external memories.

Program-controlled units of the type described can be developed, produced, and tested simply, rapidly, and cost-effectively independently of the details of the practical realization, even when they have to be adapted to special requirements.

We claim:

1. A program-controlled unit, comprising:
a bus;
chip carriers disposed one above another and connected to one another through said bus; and
semiconductor chips distributed among said chip carriers.

2. The program-controlled unit according to claim 1, wherein:
each of said semiconductor chips have terminals including at least one of input terminals and output terminals; and
each of said chip carriers have:
a lateral edge;
electrically conductive structures, said structures having contact points for connection to said terminals of respective ones of said semiconductor chips mounted thereon; and
conductor tracks running from said contact points to said lateral edge.

3. The program-controlled unit according to claim 2, wherein said conductor tracks on different ones of said chip carriers are connected to one another at least partly through said bus.

4. The program-controlled unit according to claim 1, wherein:
said chip carriers are disposed one above another in a chip carrier stack; and
said bus is a multiplicity of bus lines running laterally at said chip carrier stack.

5. The program-controlled unit according to claim 1, wherein:
said chip carriers are disposed one above another in a chip carrier stack; and
said bus is formed by a multiplicity of bus lines running laterally at said chip carrier stack.

6. The program-controlled unit according to claim 4, wherein said bus lines run vertically.

7. The program-controlled unit according to claim 4, wherein:
said chip carriers are disposed one above another in a chip carrier stack along a stack direction; and
said bus lines run along said stack direction.

8. The program-controlled unit according to claim 4, wherein said bus lines run parallel to one another.

9. The program-controlled unit according to claim 6, wherein said bus lines run parallel to one another.

10. The program-controlled unit according to claim 1, wherein:
said chip carriers disposed one above another define interspaces therebetween; and
said interspaces between said chip carriers are filled with a filling compound.

11. The program-controlled unit according to claim 3, wherein said conductor tracks and said bus lines are disposed to automatically come into contact with one another during production of said bus lines without an additional connection.

12. The program-controlled unit according to claim 3, wherein said conductor tracks and said bus lines are disposed to automatically come into contact with one another during production of said bus lines.

13. The program-controlled unit according to claim 3, wherein:
a first given subset of said conductor tracks of one chip carrier is to be connected to a given second subset of said conductor tracks of another chip carrier through a given bus line; and
said first given subset and said second given subset of said conductor tracks have courses reaching said lateral edge of a respective one of said chip carriers at a location lying directly one above another.

14. The program-controlled unit according to claim 11, wherein:
a first given subset of said conductor tracks of one chip carrier is to be connected to a given second subset of said conductor tracks of another chip carrier through a given bus line; and
said first given subset and said second given subset of said conductor tracks have courses reaching said lateral edge of a respective one of said chip carriers at a location lying directly one above another.

15. The program-controlled unit according to claim 3, wherein said conductor tracks to be connected to one another through said bus traverse a course on a respective one of said chip carriers to reach said lateral edge of said respective chip carrier at locations lying directly one above another.

16. The program-controlled unit according to claim 2, wherein said terminals do not include:
input terminals to be connected to an external memory; and
output terminals to be connected to an external memory.
